(19) United States
(12) Patent Application Publication
(10) Pub. No.: US 2021/0304992 A1
(43) Pub. Date: Sep. 30, 2021

(54) Actuation Device, In Particular For a Relay

(71) Applicant: TE Connectivity Germany GmbH, Bensheim (DE)

(72) Inventor: Matthias Kroeker, Bensheim (DE)

(73) Assignee: TE Connectivity Germany GmbH, Bensheim (DE)

(21) Appl. No.: 17/212,695

(22) Filed: Mar. 25, 2021

(30) Foreign Application Priority Data
Mar. 25, 2020 (DE) 10 2020 203 830.9

(51) Int. Cl. H01H 50/18; H01H 50/02; H01H 50/54

(52) U.S. Cl. CPC H01H 50/18; H01H 2235/01; H01H 50/546; H01H 50/02

(57) ABSTRACT

An actuation device for a relay includes a base element, a drive rod movable relative to the base element, and an actuation element moving the drive rod from a first position to a second position. The actuation element has a film made of an electroactive polymer.

### CROSS-REFERENCE TO RELATED APPLICATIONS

This application claims the benefit of the filing date under 35 U.S.C. §119(a)-(d) of German Patent Application No. 102020203830.9, filed on Mar. 25, 2020.

### FIELD OF THE INVENTION

The present invention relates to an actuation device and, more particularly, to an actuation device for a relay.

### BACKGROUND

Actuation devices are used, for example, in relays for closing and opening two fixed contacts by way of a switching bridge. Present actuation devices are heavy and require significant installation space.

### SUMMARY

An actuation device for a relay includes a base element, a drive rod movable relative to the base element, and an actuation element moving the drive rod from a first position to a second position. The actuation element has a film made of an electroactive polymer.

### BRIEF DESCRIPTION OF THE DRAWINGS

The invention will now be described by way of example with reference to the accompanying Figures, of which:

FIG. 1 is a perspective view of an actuation device according to an embodiment;

FIG. 2 is a perspective view of the actuation device of FIG. 1;

FIG. 3 is a schematic perspective view of a film according to an embodiment;

FIG. 4 is a schematic side view of a plurality of films according to an embodiment;

FIG. 5 is a sectional side view of a relay according to an embodiment with an actuation device and a drive rod in a first position;

FIG. 6 is a sectional side view of the relay with the actuation device and the drive rod in a second position;

FIG. 7 is a graph of a force profile of the actuation device;

FIG. 8 is a perspective view of a film according to an embodiment with a clamping element;

FIG. 9 is a top view of the film of FIG. 8;

FIG. 10 is a top view of a force-absorbing element;

FIG. 11 is a perspective view of the force-absorbing element of FIG. 10; and

FIG. 12 is a side view of the force-absorbing element of FIG. 10.

### DETAILED DESCRIPTION OF THE EMBODIMENT(S)

In the following, the invention shall be described by way of example in detail with reference to the drawings using embodiments of the invention. The developments and configurations illustrated there are each independent of each other and can be combined with one another. In the figures, elements that correspond to each other concerning their construction and/or function are provided with the same reference numerals. The combinations of features shown and described in the individual embodiments are only provided for illustration purposes. A feature of an embodiment may be omitted if its technical effect is not relevant for a certain application. Inversely, a further feature may be added to an embodiment if its technical effect is advantageous or necessary for a certain application.

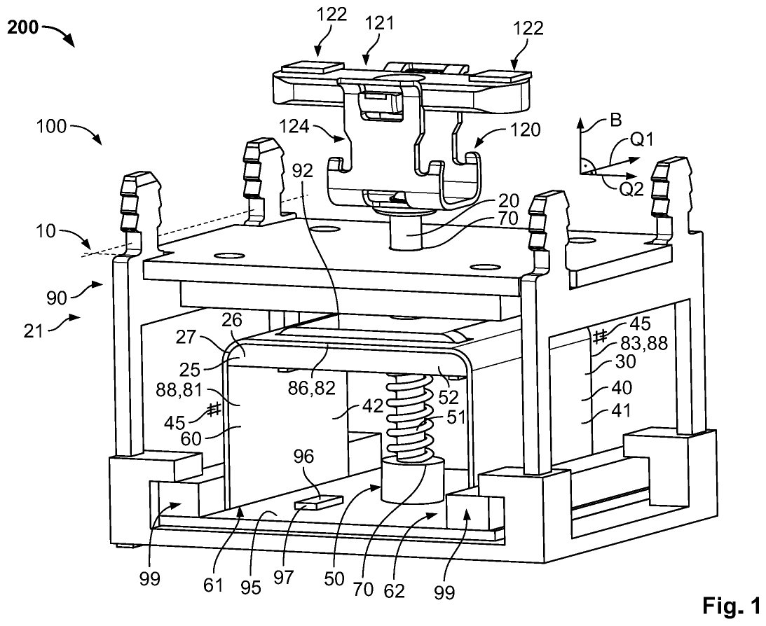

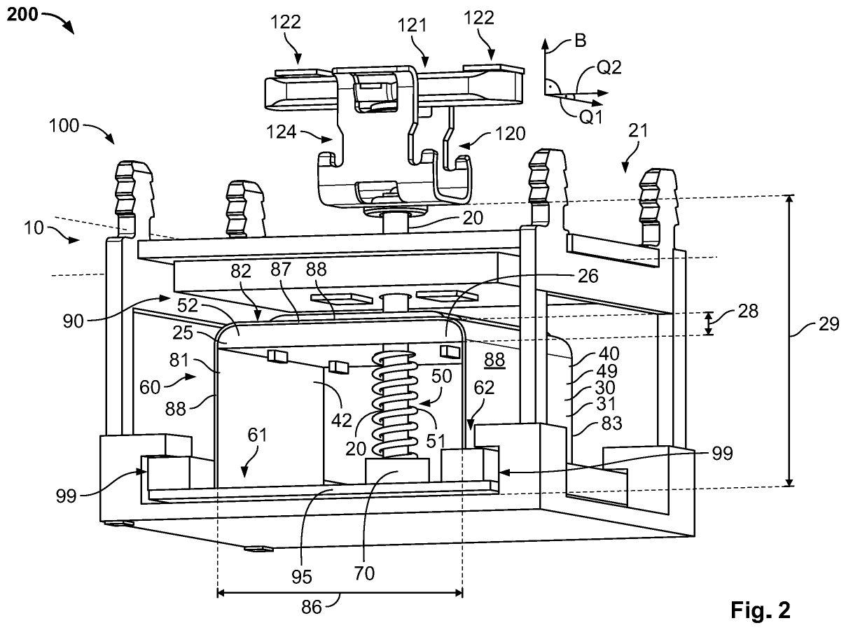

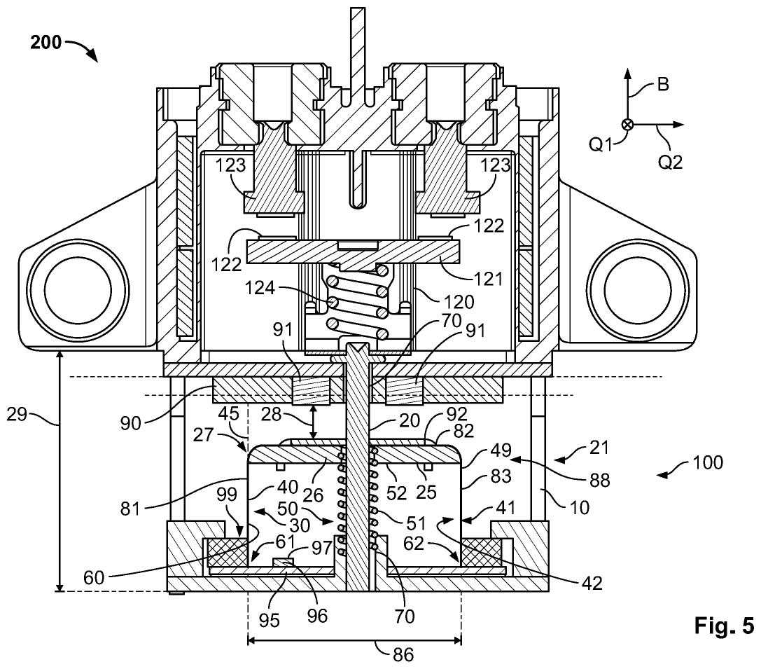

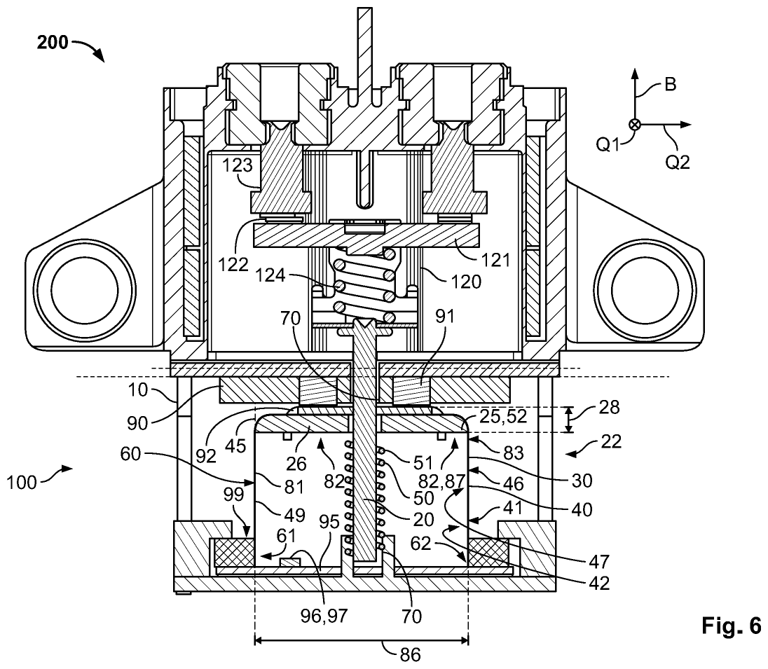

An actuation device 100 for a relay 200 according to an embodiment is shown in FIGS. 1 and 2. As can be seen, for example, in FIGS. 5 and 6, relay 200 can comprise further elements in addition to actuation device 100, in particular a switching bridge 121 connected by way of a switching bridge support 120 to a drive rod 20 of actuation device 100. Switching bridge 121 has a pair of movable contacts 122 which, depending on the position of drive rod 20, connect or do not connect a pair of fixed contacts 123 by way of switching bridge 121 and thereby open or close a connected circuit. An overtravel spring 124 between switching bridge support 120 and switching bridge 121 biases switching bridge 121 towards fixed contacts 123 and generates a pressing force which in the closed state presses movable contacts 122 against fixed contacts 123.

Actuation device 100 comprises a base element 10 that serves as a reference and a frame. Furthermore, actuation device 100 disposes of drive rod 20 which is movable relative to base element 10 along a direction of motion B. The motion of drive rod 20 can be controlled by a control current or control voltage. Drive rod 20 can be transferred from a first position 21, as shown, for example, in FIGS. 1, 2 and 5, to a second position 22, as shown, for example, in FIG. 6 by a control signal. For example, the drive rod 20 can be in the first position 21 when the control signal has a low value and in the second position 22 when the control signal has a high value. The control signal can be in particular an electrical signal, for example, a voltage. First position 21 and second position 22 are there defined relative to base element 10. The base element 10 can be mountable to further elements, for example, to a housing that comprises fixed contacts 123.

For this motion, actuation device 100 comprises an actuation element 30 which, in the embodiment shown in FIGS. 1 and 2, comprises a film 40 made of an electroactive polymer (EAP) 49. The polymer 49 can be an ionic EAP or an electronic EAP. In particular, the electroactive polymer 49 can be a dielectric polymer. The electroactive polymer 49 can be silicone or acrylic or comprise silicone or acrylic. The film 40 can synonymously be called a foil or a membrane. Compared to other configurations in which, for example, a coil is used, the configuration with an electroactive membrane or film 40 made of an electroactive polymer 49 is lighter and more compact. Furthermore, this solution can be more economical. The films 40, in an embodiment, have a thickness between 5 and 500 μm.

Actuation element 30 is operatively arranged between base element 10 and drive rod 20, as shown in FIGS. 1 and 2, and it therefore establishes an operative connection between the two elements. In the present case, it is also arranged geometrically between base element 10 and drive rod 20.

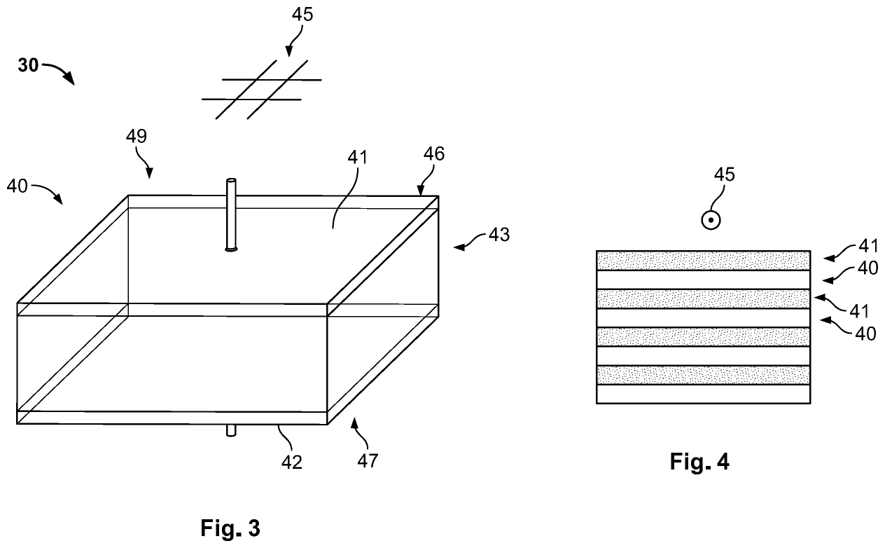

The principle of action of film 40 with electroactive polymer 49 is shown in FIG. 3. An elastic layer 43, for example made of silicone, is coated with electrically conductive material on first flat side 46 and second flat side 47. The conductive material can be printed on the elastic layer 43. The coatings form a first electrode 41 and a second electrode 42, respectively. The two electrodes 41, 42 act like a capacitor. When a high voltage is applied between two electrodes 41, 42, they are drawn to one another and thereby squeeze elastic layer 43 together. This leads to a reduction in the thickness of elastic layer 43 and, as a result, to a greater expansion in plane of extension 45 of film 40. As shown in FIG. 4, several such films 40 can optionally be stacked on top of one another, for example, in order to obtain a greater force. The stacked films 40 can be in direct contact and can be stacked with flat sides abutting against one another.

As shown in FIGS. 1 and 2, actuation device 100 further comprises a biasing device 50 which comprises in particular a spring 51, such as a helical spring, and which acts upon a force-absorbing element 25 of drive rod 20. Biasing device 50 attempts to push drive rod 20 to second position 22 when drive rod 20 is in first position 21 in that it exerts a force upon force-absorbing element 25 and therefore upon the remainder of drive rod 20 that is firmly connected to force-absorbing element 25. In second position 22 there can be no force exerted by biasing device 50 or such force can be very small, for example, only 5 percent or less than the force in first position 21.

In order to hold drive rod 20 in second position 22, actuation device 100 comprises a magnetic holding device 90 shown in FIGS. 5 and 6, in the present case magnets 91 fixedly connected to base element 10 and a ferromagnetic element 92 in the form of a plate which is movable relative thereto and fixedly connected to the remainder of drive rod 20. Since the magnetic holding forces acting have a rapidly declining profile, magnetic holding device 90 acts primarily in the vicinity of second position 22 shown in FIG. 6 and prevents the drive rod 20 from coming loose from the second position 22 due to vibration. The effect can be present in particular when movable contacts 122 touch fixed contacts 123. The magnetic force can then compress overtravel spring 124, which in turn presses movable contacts 122 against fixed contacts 123. The contact force between movable contacts 122 and fixed contacts 123 is then substantially independent of the force that biasing device 50 generates with spring 51. In another embodiment, the magnetic holding device 90 has an electromagnet.

In another embodiment, a differently configured holding device can be present which holds the drive rod 20 in the second position 22, for example, by way of a latching mechanism. The latching mechanism, like the magnetic holding device 90, can assume part of the force, e.g., in the region of the overtravel build-up, which presses the movable contacts 122 against the fixed contacts 123 and thereby supports further force-generating elements such as springs.

In the embodiment shown, film 40 comprises a first film section 81, an adjoining second film section 82, and an adjoining third film section 83, which overall form a U-shape as shown in FIGS. 1 and 2. First film section 81 and third film section 83 are spaced from one another along a second transverse direction Q2 which runs perpendicular to direction of motion B of drive rod 20, but each run parallel to direction of motion B and parallel to one another. The plane of extension 45 in these sections 81 and 83 is therefore parallel to direction of motion B. Plane of extension 45 in first section 81 and in third section 83 also runs along a first transverse direction Q1 which is perpendicular to direction of motion B and perpendicular to second transverse direction Q2. In another embodiment, the direction of motion B of the drive rod 20 can be at an angle to the plane of extension 45 of the film 40 or actuation element 30.

As shown in FIG. 2, second film section 82 forms a connection section 87 against which force-absorbing element 25 abuts, but which is not necessarily responsible for a motion of drive rod 20. Such motion takes place due to a change in length in the region of first section 81 and third section 83 which are each partial sections 88 of film 40. In an embodiment, the drive rod 20 can suspend from the connection section 87. The film 40 can form a loop which encloses a force-absorbing element 25 of the drive rod 20 and/or from which the force-absorbing element 25 is suspended.

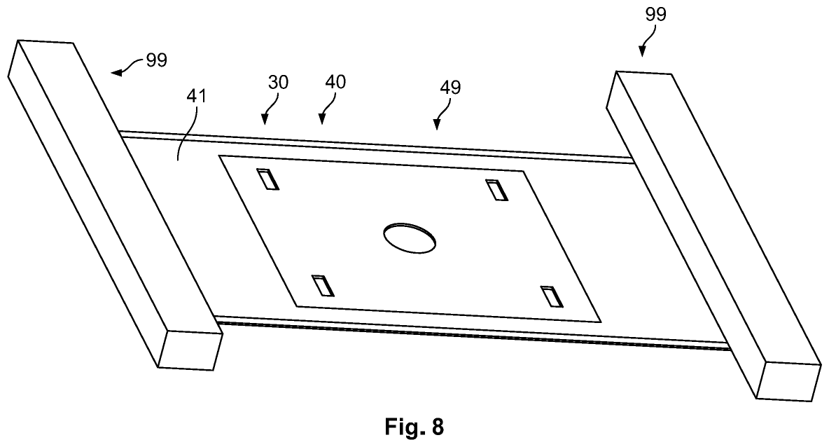

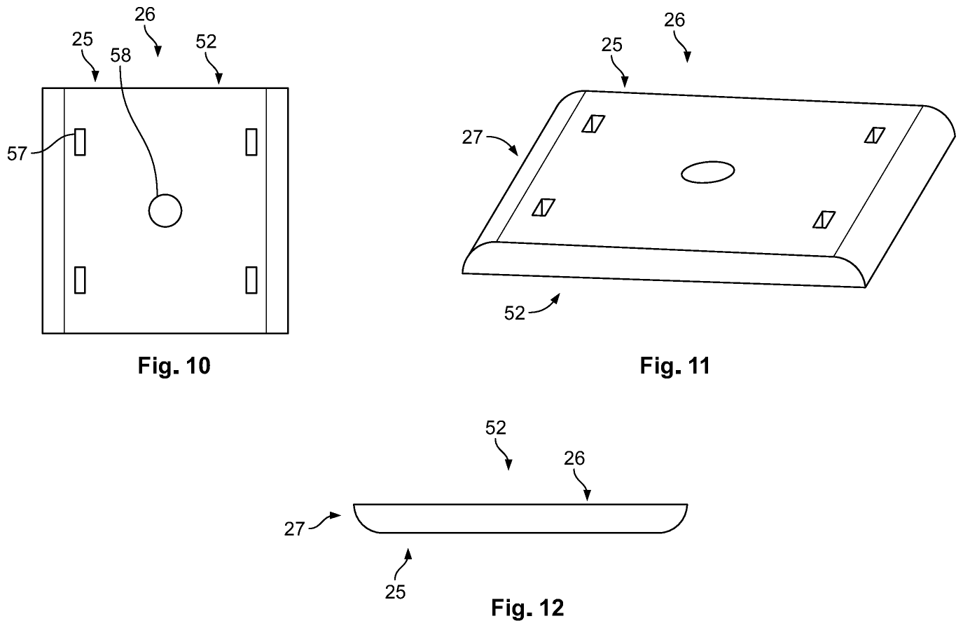

Film 40 in second film section 82 is clamped or otherwise mechanically held between force-absorption element 25, which is configured as a plate 26 with rounded edges 27 as shown in FIGS. 11 and 12, and ferromagnetic element 92 of magnetic holding device 90, which is likewise configured as a plate 26. Connection elements on ferromagnetic element 92 protrude through holes 57 in film 40 and force-absorbing element 25, shown in FIGS. 8-11.

In first position 21 shown in FIG. 5, the resilient force of elastic layer 43 of film 40 acts against the force of spring 51 and the force of magnetic holding device 90 and holds drive rod 20 without a stop in first position 21. When actuation element 30 is actuated by applying a high voltage between electrodes 41, 42, the force of elastic layer 43 is compensated for in part by the attracting force of electrodes 41 and 42 to one another, so that the forces in the direction of second position 22 predominate and drive rod 20 moves towards second position 22, shown in FIG. 6. As long as the voltage is applied, drive rod 20 then remains in second position 22, preventing vibrations due to striking the stop. If the voltage is removed, the resilient force of elastic layer 43 prevails again in film 40 and drive rod 20 is retracted to first position 21. In another embodiment, a force generated by the actuation element 30 holds the drive rod 20 against a stop.

In addition to first position 21 and second position 22, further positions can be present, for example, a third position which is disposed between first position 21 and second position 22 and in which drive rod 20 is held, for example, due to an equilibrium of forces. A continuous spectrum of positions between first position 21 and second position 22 is also possible if, for example, the voltage between two electrodes 41, 42 can be adjusted steplessly.

Drive rod 20 is held linearly movable in base element 10 by way of guide elements 70, shown in FIGS. 1, 2, 5, and 6.

Film 40 shown is configured as a strip 60 in which a first end 61 and a second end 62 disposed opposite to first end 61 are clamped between a printed circuit board 95 and a clamping element 99 and are thereby held mechanically, as shown in FIGS. 1 and 2. A remainder to the strip 60 can be free; not attached or clamped in on longitudinal sides. As a result of the clamping, electrical contact can also be established at the same time, for example, via conductive elements on printed circuit board 95 or clamping element 99. Electrical components 96, for example, a step-up converter 97 which converts an incoming voltage to a higher voltage can be present on printed circuit board 95. In another embodiment, electrical components for control can be present outside the actuation device 30. Force-absorbing element 25 of drive rod 20 and ferromagnetic element 92 can likewise be used to establish an electrical contact with electrodes 41, 42. Force-absorbing element 25 fulfills a dual function and at the same time serves as a support element 52 for biasing device 50.

A spacing 86 between first film section 81 and third film section 83, shown in FIGS. 2, 5, and 6, can be 100 to 500 percent of a spacing 28 between first position 21 and second position 22 of drive rod 20. Furthermore, spacing 86 can be 100 to 500 percent of a length 29 of drive rod 20. As a result, tolerances in the region of film 40 can lead to minor errors in the motion of drive rod 20. The error tolerance is further improved by the symmetrical configuration of film sections 81, 83. For example, they can be merged into one another by way of a mirror symmetry or a twofold rotational symmetry. The mirror plane or axis of rotation, respectively, can run parallel to the direction of motion B of the drive rod 20. The drive rod 20 can likewise be configured to be symmetrical in order to enable simple assembly. Drive rod 20 and biasing device 50 are disposed at least in part between two film sections 81, 83 spaced apart, so that actuation device 100 is compact. The two film sections 81, 83 can be two separate films, in an embodiment, to save film material.

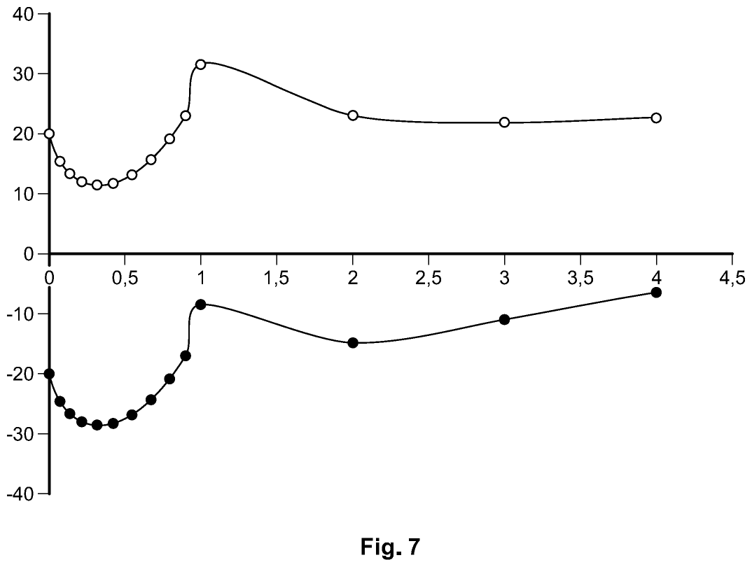

A force profile of actuation device 100 is shown in FIG. 7. The upper and lower graphs correspond to the two cases where a voltage or no voltage is applied to film 40. The force profile is the sum of the resilient force of elastic layer 43, the force generated by two electrodes 41, 42, the magnetic force by magnetic holding device 90, the force of spring 51 of biasing device 50, and the force of overtravel spring 124 which is built up when contacts 122, 123 are closed.

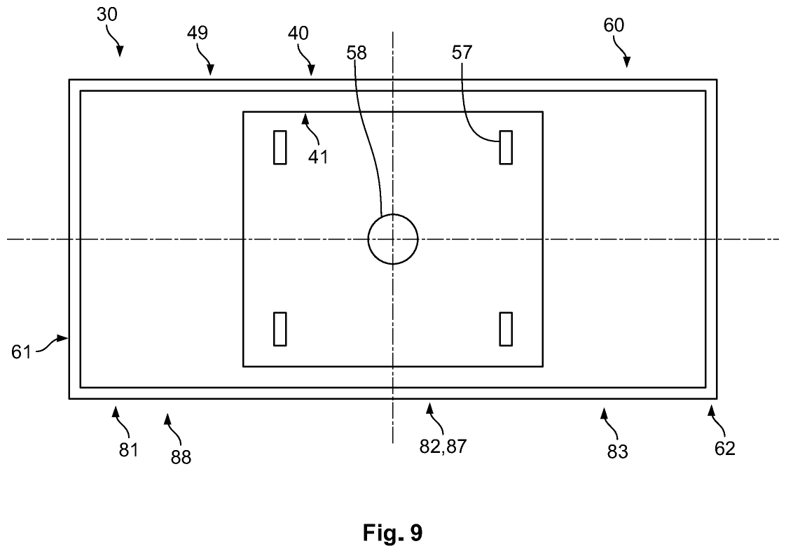

As can be seen in FIGS. 8 and 9, there does not necessarily have to be a wide-surface coating present with a conductive material in the region of second section 82 of film 40. In this region, for example, parts of elastic layer 43 can be seen due to the lack of such an electrode 41 and 42. In second film section 82, holes 57 for the mechanical connection of ferromagnetic element 92 to force-absorbing element 21 and a hole 58 for passing drive rod 20 through are also present. It can also be seen that elastic layer 43 is also exposed in the region of the edge of strip 60 and no electrodes 41, 42 are formed there. This can prevent, for example, undesired contacting.

What is claimed is:

1. An actuation device for a relay, comprising:
a base element;
a drive rod movable relative to the base element; and
an actuation element moving the drive rod from a first position to a second position, the actuation element has a film made of an electroactive polymer.

2. The actuation device of claim 1, wherein the actuation element is arranged between the base element and the drive rod.

3. The actuation device of claim 1, wherein a conductive material is printed onto at least one side of the film.

4. The actuation device of claim 1, wherein the actuation element has a plurality of films stacked on top of one another.

5. The actuation device of claim 1, wherein the drive rod is held in a movable manner.

6. The actuation device of claim 1, wherein a direction of motion along which the drive rod moves from the first position to the second position is parallel to a plane of extension of the film.

7. The actuation device of claim 1, further comprising a magnetic holding device that holds the drive rod in the second position.

8. The actuation device of claim 1, further comprising a biasing device generating a force upon the drive rod toward the second position when the drive rod is in the first position.

9. The actuation device of claim 1, wherein the film is a strip attached at a pair of oppositely disposed ends.

10. The actuation device of claim 1, wherein the actuation element has a pair of film sections spaced from one another perpendicular to a direction of motion of the drive rod.

11. The actuation device of claim 10, wherein the film sections are each a partial section of a single film.

12. The actuation device of claim 11, wherein a force absorbing element of the drive rod abuts against a connection section between the film sections.

13. The actuation device of claim 10, wherein the drive rod is disposed at least in part between the pair of film sections.

14. The actuation device of claim 10, further comprising a biasing device generating a force upon the drive rod toward the second position when the drive rod is in the first position.

15. The actuation device of claim 14, wherein the biasing device is disposed at least in part between the pair of film sections.

16. The actuation device of claim 1, further comprising a printed circuit board having a plurality of electric components attached thereto for controlling motion of the drive rod.

17. The actuation device of claim 1, wherein the film has an electrode that is electrically contacted by mechanical clamping.

18. A relay, comprising:
an actuation device including a base element, a drive rod movable relative to the base element, and an actuation element moving the drive rod from a first position to a second position, the actuation element has a film made of an electroactive polymer.
